(19) United States
(12) Patent Application Publication
(10) Pub. No.: US 2010/0177542 A1
(43) Pub. Date: Jul. 15, 2010

(54) POWER TRANSISTOR CHIP WITH BUILT-IN START-UP TRANSISTOR AND APPLICATION CIRCUIYT THEREOF

(75) Inventor: CHIH-FENG HUANG, CHUPEI CITY (TW)

Correspondence Address: G. LINK CO., LTD., 3550 BELL ROAD, MINOOKA, IL, 60447, US

(73) Assignee: Richtek Technology Corp., ChuPei CITY (TW)

(21) Appl. No.: 12/427,236

(22) Filed: Apr. 21, 2009

(30) Foreign Application Priority Data
Jan. 9, 2009 (TW) 098100759

(51) Int. Cl. H02M 7/217

(52) U.S. Cl. 363/127

(57) ABSTRACT

A power transistor chip with a built-in start-up transistor and an application circuit thereof provides a junction field effect transistor in association with a metal oxide semiconductor field effect transistor to act as a start-up circuit of an AC/DC voltage converter. The start-up circuit can be turned off after the PWM circuit of the AC/DC voltage converter operates normally to conserve the consumption of the power. Besides, the junction field effect transistor and the metal oxide semiconductor field effect transistor are built in the power transistor chip. Because the junction field effect transistor and the metal oxide semiconductor field effect are fabricated with the same manufacturing process as the power transistor, it is capable of simplifying the entire process and lowering the production cost due to no additional mask and manufacturing process.

### BACKGROUND OF THE INVENTION

1. Field of the Invention

The present invention is related to a voltage regulator circuit and particularly to a power transistor chip with a junction field effect transistor (JEFT) and metal oxide semiconductor field effect transistor (MOSFET) built therein and an AC/DC voltage converter employing the power transistor chip.

2. Brief Description of the Related Art

Due to the semiconductor technology being developed progressively, the digital products such as the computer and the peripherals thereof are capable of being upgraded continuously. The fast change of the manufacturing process for the semiconductor results in a variety of demands for the power source of the integrated circuit (IC) employed in the computer and the peripherals thereof. Hence, various combinations of voltage regulators using such as the boost converter and the buck converter to meet the need of different power sources of the integrated circuit become one of the most important factors to offer versatile digital products. The AC/DC voltage converter is widely taken as the primary stage circuit of the voltage regulator circuit because it is capable of converting the AC power input to the needed steady direct power output.

Referring to FIG. 1, a circuit diagram of the conventional AC/DC voltage converter is illustrated. The AC/DC voltage converter 10 includes a bridge type rectifying circuit 11, a power transistor chip 12. a pulse width modulation (PWM) circuit 13, a start-up circuit 14, a transformer circuit 15, a filtering and feedback circuit 16 and a working power circuit 17. The pulse width modulation circuit 13 produces the modulated PWM signal to control and output the direct power output Vₒ according to the magnitude of the feedback voltage of the direct power output Vₒ. However, the pulse width modulation circuit 13 usually is driven by a low voltage direct power and there is no direct power available for operating the pulse width modulation circuit 13 at the time of the AC/DC voltage converter 10 initiating the work thereof. Therefore, it is necessary to use the start-up circuit 14 and the working power circuit 17 to supply the successive power needed by the pulse width modulation circuit 13.

When the AC/DC voltage converter 10 initiates the work thereof, the output terminal of the bridge type rectifying circuit 11 outputs a rippling direct power to the pulse width modulation circuit 113 via the resistance in the start-up circuit 14 for operating the pulse width modulation circuit 13. Then, the pulse width modulation circuit 13 performs the normal job thereof afterward according to the magnitude of the feedback voltage of the output direct power Vₒ and produces the modulated PWM signal such that the time duration of ON and OFF of the power transistor can be controlled for outputting a steady direct power Vₒ. The working power circuit 17, which is connected to the transformer circuit 15, supplies more steady working power for the pulse width modulation circuit 13 performs the job thereof much steadily after the AC/DC voltage converter 10 is started up and outputs the steady direct power Vₒ.

Although the preceding way allows the AC/DC voltage converter to work normally, the start-up circuit 14 keeps in a state of supplying the power to the pulse width modulation circuit 13 unnecessarily. In order to improve the deficiency, the depletion metal oxide semiconductor field effect transistors (Depletion MOSFET) 221, 331 are employed instead to output a start-up signal st via the pulse width modulation circuit 23 or 33 to turn off the operation of the depletion metal oxide semiconductor field effect transistors 221, 331 respectively for conserving the power consumption.

The difference between FIG. 2 and FIG. 3 is in that the depletion metal oxide semiconductor field effect transistors 221, 331 are integrated in the power transistor chip 22 and the pulse width modulation circuit 33 respectively for starting up the AC/DC voltage converter. However, the manufacturing process of the chip becomes more complicated due to the additional process of the channel (N channel or P channel) of the depletion metal oxide semiconductor field effect transistors 221, 331.

### SUMMARY OF THE INVENTION

Accordingly, an object of the present invention is to provide a power transistor chip and an AC/DC voltage converter employing the power transistor chip, which has both built-in junction field effect transistor and metal oxide semiconductor field effect transistor to act as a start-up circuit such that not only the power consumption is conserved but also no additional mask and process are involved for simplifying the manufacturing process and lowering the production cost.

In order to achieve the preceding object, the power transistor chip with a built-in start-up transistor according to the present invention is adaptable to the AC/DC voltage converter and comprises a first pin, a second pin, a third pin, a fourth pin, a fifth pin, a power transistor, a metal oxide semiconductor field effect transistor and a junction field effect transistor; wherein, the power transistor acts as a power switch of the AC/DC voltage converter and has a first source/drain, a second source/drain and a power transistor gate with the first source/drain coupling with the first pin, the second source/drain coupling with the second pin and the power transistor gate coupling with the third pin; the metal oxide semiconductor field effect transistor has a fifth source/drain, a sixth source/drain and a metal oxide semiconductor field effect transistor gate with the fifth source/drain coupling the first pin and the sixth source/drain coupling with the fourth pin; and the junction field effect transistor together with the metal oxide semiconductor field effect transistor acts as the start-up circuit of the AC/DC voltage converter and has a third source/drain, a fourth source/drain and a junction field effect transistor gate with the third source/drain coupling with said first pin, the fourth source/drain coupling with the metal oxide semiconductor field effect transistor gate and the junction field effect transistor gate coupling with the fifth pin.

Further, the AC/DC voltage converter according to the present invention is capable of converting the AC power input to the steady DC power output and further comprises a bridge type rectifying circuit, a transformer circuit, a pulse width modulation circuit, a filtering and feedback circuit and a working power circuit in addition to the preceding power transistor chip with the built-in start-up transistor.

Wherein, the bridge type rectifying circuit has a power input terminal, which receives the AC power input, and a rectifying output terminal; the transformer circuit has a primary coil, a secondary coil and an auxiliary coil with the primary coil having an terminal coupling with the rectifying output terminal and another terminal coupling with the first pin of the power transistor chip, i.e., coupling with the first source/drain of the power transistor, the fifth source/drain of the metal oxide semiconductor field effect transistor and the third source/drain of the junction field effect transistor.

The pulse width modulation circuit has a start-up power control terminal, a working power terminal, a pulse width modulation signal output terminal and a current sensing terminal with the start-up power control terminal coupling with the fifth pin of the power transistor, i.e., the junction field effect transistor gate to control ON and OFF of the junction field effect transistor and then ON and OFF of the metal oxide semiconductor field effect transistor, the working power terminal coupling with the fourth pin of the power transistor chip, i.e., the sixth source/drain, to receive a start-up power from the metal oxide semiconductor field effect transistor, the pulse width modulation signal output terminal coupling with the third pin of the power transistor chip, i.e., the power transistor gate to output a pulse width modulation signal according to the magnitude of a feedback voltage and the current sensing terminal coupling with the second pin to sense a current passing through the power transistor.

The working power circuit couples with the auxiliary coil and the working power terminal of the pulse width modulation circuit to supply a power needed by the pulse width modulation circuit at the time of the start-up power output by the metal oxide semiconductor field effect transistor being turned off by the pulse width modulation circuit; and the filtering and feedback circuit couple with the secondary coil to filter and output the steady DC power and supply a feedback voltage needed by the pulse width modulation circuit.

In short, a power transistor chip and an AC/DC voltage converter using the power transistor chip according to the present invention has a junction field effect transistor associated with the metal oxide semiconductor field effect transistor to act as a start-up circuit of the AC/DC voltage converter. The junction field effect transistor and the metal oxide semiconductor field effect transistor can be turned off after the PWM circuit of the AC/DC voltage converter operates normally to conserve the consumption of the power. Besides, the junction field effect transistor and the metal oxide semiconductor field effect transistor are built in the power transistor chip such that the junction field effect transistor and the metal oxide semiconductor field effect transistor can be fabricated with the same manufacturing process as power transistor chip such that it is capable of simplifying the process and lowering the production cost due to no additional mask and manufacturing process.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a circuit diagram illustrating the conventional AC/DC voltage converter;

FIG. 2 is a circuit diagram illustrating the conventional AC/DC voltage converter employing the depletion metal oxide semiconductor field effect transistor (Depletion MOSFET) as a start-up circuit;

FIG. 3 is a circuit diagram illustrating another conventional AC/DC voltage converter similar to FIG. 2;

FIG. 4 is a circuit diagram illustrating an AC/DC voltage converter of a preferred embodiment according to the present invention;

FIG. 5 is a diagram illustrating the junction field effect transistor and the metal oxide semiconductor field effect transistor of the power transistor chip according to the present invention in a state of ON; and

FIG. 6 is a diagram illustrating the junction field effect transistor and the metal oxide semiconductor field effect transistor of the power transistor chip according to the present invention in a state of OFF.

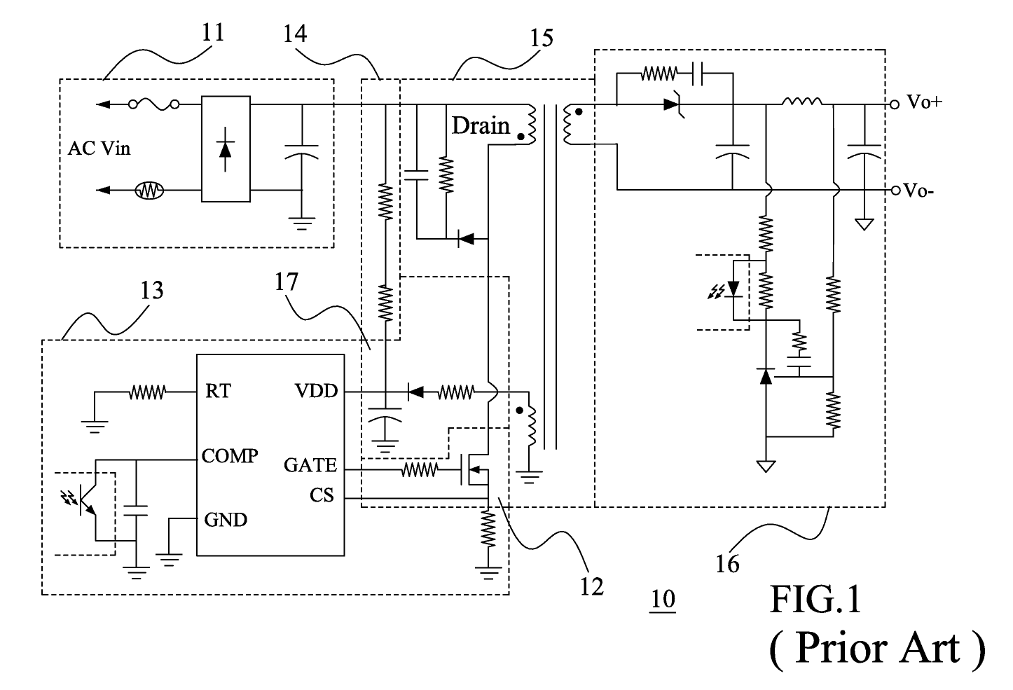

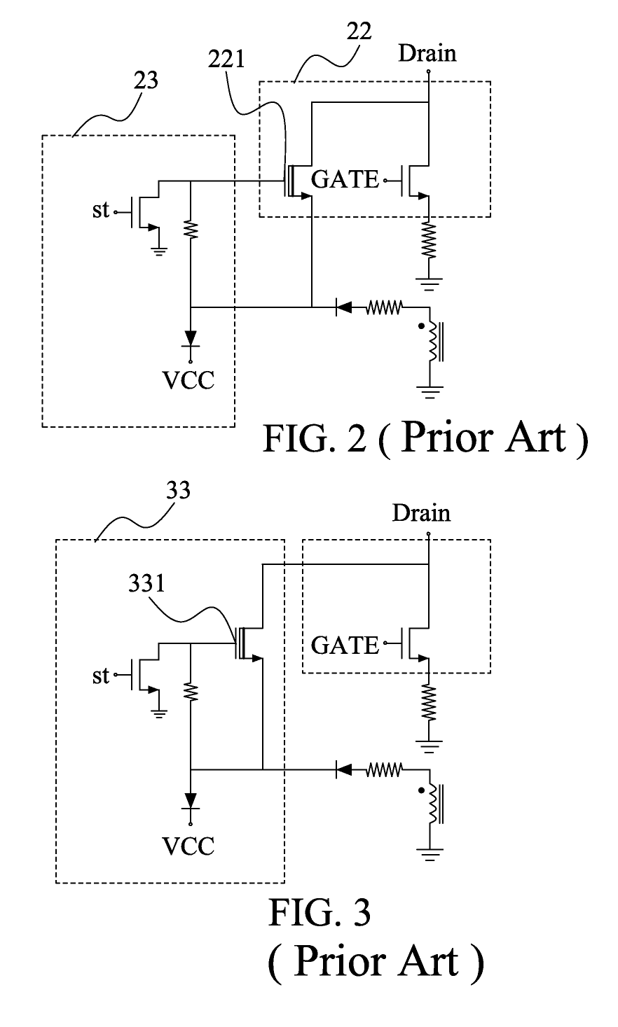

### DETAILED DESCRIPTION OF THE INVENTION

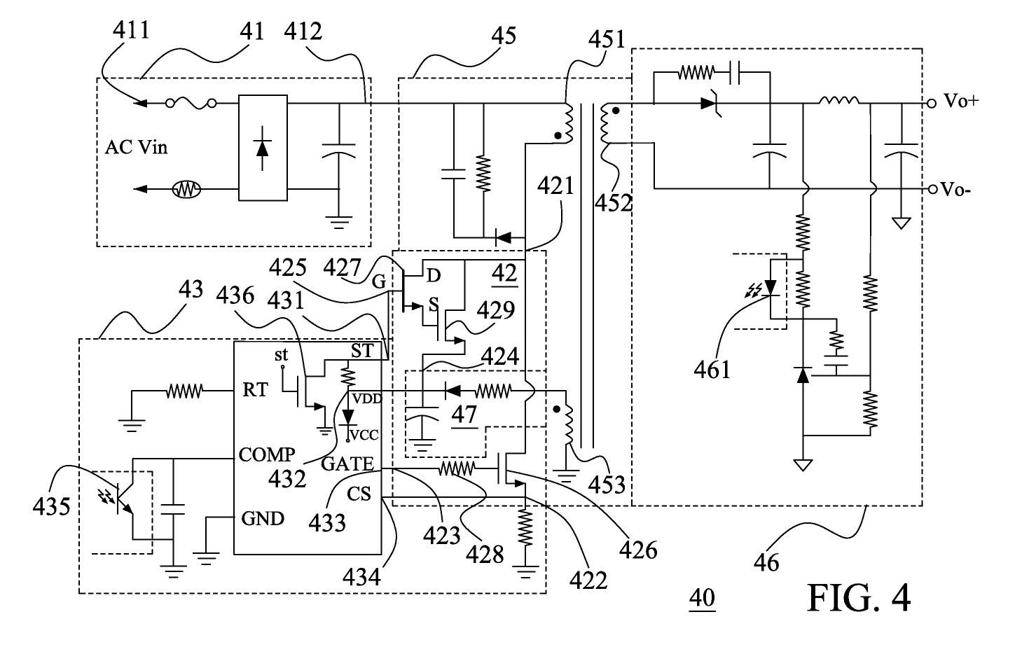

Referring to FIG. 4, an AC/DC voltage converter of the preferred embodiment according to the present invention is illustrated. The AC/DC voltage converter 40 is capable of converting the AC input power Vᵢₙ coming from the power terminal 411 to a steady direct output voltage Vₒ. It can be seen in FIG. 4 that the AC/DC voltage converter 40 includes a bridge type rectifying circuit 41, a power transistor chip 42, a pulse width modulation circuit 43, a transformer circuit 45, a filtering and feed back circuit 46 and a working power circuit 47.

The power transistor chip 42 shown in FIG. 4 has a first pin 421, a second pin 422, a third pin 423, a fourth pin 244, a fifth pin 425, a power transistor 426, a metal oxide semiconductor field effect transistor 429 and a junction field effect transistor 427. The junction field effect transistor 427 and the metal oxide semiconductor field effect transistor 429, which acts as the start-up circuit of the AC/DC voltage converter 40, are built in the power transistor chip 42 to simplify the manufacturing process of the chip arranged in the AC/DC voltage converter 40. Although the power transistor 426, the metal oxide semiconductor field effect transistor 429 and the junction field effect transistor 427 are exemplified with N-type metal oxide semiconductor field effect transistor and N-type junction field effect transistor and the resistance 428 connected to the gate of the power transistor 426 is built in the power transistor chip 42, persons skill in the art realize different type transistors such as the P-type metal oxide semiconductor field effect transistor or P-type junction field effect transistor can be adopted as well. Further, the built-in resistance 428 can be optionally integrated in a chip with the pulse width modulation circuit 43 instead of being included in the power transistor chip 42.

Wherein, the power transistor 426, which is a power switch of the AC/DC voltage converter 40, has the first source/drain coupling with the first pin 421, the second source/drain coupling with the second pin 422 and the power transistor gate coupling with the third pin 423. The metal oxide semiconductor field effect transistor 429 has a fifth source/drain to couple with the first pin of power transistor chip 42, a sixth source/drain to couple with fourth pin 424 of the power transistor 42 and a metal oxide semiconductor field effect transistor gate. The junction field effect transistor 427 has the third source/drain D coupling with the first pin 421 of the power transistor 42, the fourth source/drain S coupling with the metal oxide semiconductor field effect transistor gate and the gate G coupling with the fifth pin 425 of the power transistor 42.

When the AC/DC voltage converter 40 is initiated to work, the bridge type rectifying circuit 41 receives the AC power input Vᵢₙ from the power source terminal 411 and rectifying the full wave of the AC power input Vᵢₙ such that a rippling direct power is output to the first pin 421 via a primary coil of the transformer circuit 451, which has an terminal coupling with the rectifying output terminal 412 of the rectifying circuit 41 and another terminal thereof coupling with the first pin 421 of the power transistor chip 42.

In order to supply the power to operate the pulse width modulation circuit 43, the working power terminal 432 of the pulse width modulation circuit 43 couples with the fourth pin 424 of the power transistor chip 42, i.e., the sixth source/drain of the metal oxide semiconductor field effect transistor 429. Meanwhile, the start-up signal st output by the pulse width modulation circuit 43 is a low reference level signal and the built-in transistor 436 is still in a state of OFF such that the start-up power control terminal 431 of the pulse width modulation circuit 43 has the VCC potential.

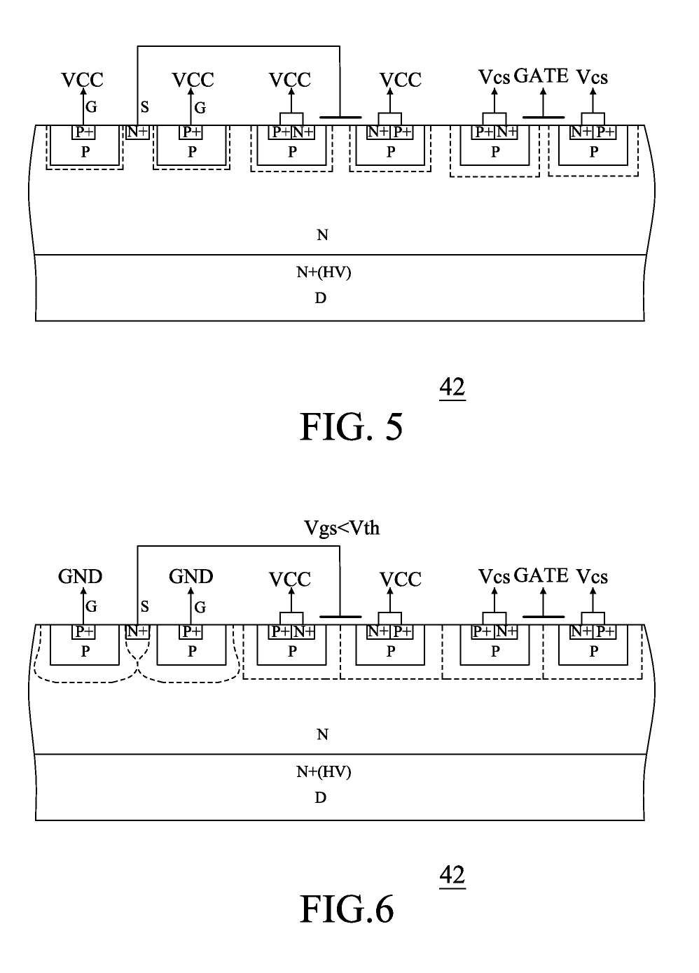

Besides, the start-up power control terminal 431 couples with the fifth pin 425 of the power transistor chip 42, i.e., the gate G of the junction field effect transistor 427. Hence, the junction field effect transistor 427 is ON and the fourth source/drain S thereof has a high potential to drive the metal oxide semiconductor field effect transistor (See FIG. 5) such that the rippling direct power output by the bridge type rectifying circuit 41 can be transmitted to the sixth source/drain of the metal oxide semiconductor field effect transistor 429, i.e., the fourth pin 424 of the power transistor 42.

Meanwhile, the pulse width modulation circuit 43 obtains the power for initiating the operation and starting up the work thereof by means of the working power end 432 thereof coupling with the sixth source/drain of the metal oxide semiconductor field effect transistor 429. In addition, the pulse width modulation circuit 43 produces the modulated PWM signal in accordance with the magnitude of the feedback voltage of the direct power Vₒ output by the AC/DC voltage converter 40 and the current of the power transistor chip 42, which is sensed from the current sensing terminal 434. Then, the modulated PWM signal is sent to the PWM signal output terminal 433 and transmitted to the gate of the power transistor of the power transistor chip 42 via the third pin 423 and the resistance 428 to control the time duration of ON and OFF of the power transistor 426 such that the AC/DC voltage converter 40 is capable of outputting a steady direct power Vₒ.

When the pulse width modulation circuit 43 initiates to work, the secondary coil 452 is induced a voltage, and then the voltage is filtered by the filtering and feedback circuit 46, which couples with the secondary coil 452, to output the steady direct power Vₒ. The reference feedback voltage needed by the pulse width modulation circuit 43 is obtained by means of the isolated detection of a light emitting diode 461 and an optical transistor 435 in the filtering and feedback circuit 46.

In addition, an auxiliary coil 453 of the transformer circuit 45 produces an induced voltage simultaneously and the induced voltage is filtered and transmitted to the working power terminal 432 by the working power circuit 47, which couples with the auxiliary coil 453. Under this circumstance, the steady working power supplied by the working power circuit 47 has been capable of meeting the need of much steadiness of the pulse width modulation such that the pulse width modulation circuit 43 raises the start-up signal st to a high reference level to activate the built-in transistor 436 for lowering the potential of the start-up control terminal 431 to the GND ground potential. In this way, it creates a reverse bias voltage between the fourth source/drain S and the gate G of the junction field effect transistor 427 to cause pinch-off and then to off the metal oxide semiconductor field effect transistor 429 as shown in FIG. 6 such that the start-up power output by the metal oxide semiconductor field effect transistor 429 is turned off after the steady working power supplied by the working power circuit 47 is capable of constantly offering the power required by the pulse width modulation circuit 43. In this way, the power consumption of the AC/DC voltage converter 40 is conserved significantly.

Referring to FIGS. 5 and 6, the power transistor chip 42 according to the preferred embodiment of the present invention provides the built-in metal oxide semiconductor field effect transistor 429 and the built-in junction field effect transistor 427. Further, similar doped structures are provided between the junction field effect transistor 427, the metal oxide semiconductor field effect transistor 429 and the power transistor 426 such that the identical manufacturing process is capable of being performed for fabricating the power transistor 426, the junction field effect transistor 427 and the metal oxide semiconductor field effect transistor 429 with no additional mask and process. Therefore, the entire process is simplified and the production cost is lowered advantageously.

While the invention has been described with referencing to a preferred embodiment thereof, it is to be understood that modifications or variations may be easily made without departing from the spirit of this invention, which is defined by the appended claims.

What is claimed is:

1. A power transistor chip, which is adaptable to an AC/DC voltage converter, comprising:
a first pin;
a second pin;
a third pin;
a fourth pin;
a fifth pin;
a power transistor acting as a power switch of said AC/DC voltage converter and having a first source/drain, a second source/drain and a power transistor gate, wherein said first source/drain couples with said first pin, said second source/drain couple with said second pin and said power transistor gate couple with said third pin;
a metal oxide semiconductor field effect transistor having a fifth source/drain, a sixth source/drain and a metal oxide semiconductor field effect transistor gate, wherein said fifth source/drain couples with said first pin and said sixth source/drain couples with said fourth pin; and
a junction field effect transistor together with said metal oxide semiconductor field effect transistor acting as a start-up circuit of said AC/DC voltage converter and having a third source/drain, a fourth source/drain and a junction field effect transistor gate, wherein said third source/drain couples with said first pin, said fourth source/drain couples with said metal oxide semiconductor field effect transistor gate and said junction field effect transistor gate couples with said fifth pin.

2. The power transistor chip as defined in claim 1 further comprises a resistance between said power transistor gate and said third pin.

3. The power transistor chip as defined in claim 1, wherein said power transistor is an N-type metal oxide semiconductor field effect transistor.

4. The power transistor chip as defined in claim 1, wherein said junction field effect transistor is an N-type junction field effect transistor and said metal oxide semiconductor field effect transistor is an N-type metal oxide semiconductor field effect transistor.

5. An AC/DC voltage converter, which is capable of converting an AC power to a steady DC power, comprising:
a power transistor acting as a power switch of said AC/DC voltage converter and having a first source/drain, a second source/drain and a power transistor gate;
a metal oxide semiconductor field effect transistor having a fifth source/drain, a sixth source/drain and a metal oxide semiconductor field effect transistor gate, wherein said fifth source/drain coupling with said first source/drain;
a junction field effect transistor together with said metal oxide semiconductor field effect transistor acting as a start-up circuit of said AC/DC voltage converter and having a third source/drain, a fourth source/drain and a junction field effect transistor gate, wherein said third source/drain couples with said first source/drain and said fourth source/drain couples with said metal oxide semiconductor field effect transistor gate;
a bridge type rectifying circuit having a power input terminal, which receives the AC power, and a rectifying output terminal;
a transformer circuit having a primary coil, a secondary coil and an auxiliary coil, wherein said primary coil has an terminal coupling with said rectifying output terminal and another terminal coupling with said first source/drain;
a pulse width modulation circuit having a start-up power control terminal, a working power terminal, a pulse width modulation signal output terminal and a current sensing terminal, wherein said start-up power control terminal couples with said junction field effect transistor gate to control ON and OFF of said junction field effect transistor and then control ON and OFF of said metal oxide semiconductor field effect transistor, said working power terminal couples with said sixth source/drain to receive a start-up power from said metal oxide semiconductor field effect transistor, said pulse width modulation signal output terminal couples with said power transistor gate to output a pulse width modulation signal according to the magnitude of a feedback voltage for modulating said DC power and said current sensing terminal couples with said second source/drain to sense a current passing through said power transistor;
a working power circuit coupling with said auxiliary coil and said working power terminal to supply a power needed by said pulse width modulation circuit at the time of said start-up power being off by said pulse width modulation circuit; and
a filtering and feedback circuit coupling with said secondary coil to filter and output the DC power and supply a feedback voltage needed by said pulse width modulation circuit.

6. The AC/DC voltage converter as defined in claim 5, further comprising a resistance between said power transistor gate and said pulse width modulation signal output terminal.

7. The AC/DC voltage converter as defined in claim 5, wherein said power transistor is an N-type metal oxide semiconductor field effect transistor.

8. The AC/DC voltage converter as defined in claim 5, wherein said junction field effect transistor is an N-type junction field effect transistor and said metal oxide semiconductor field effect transistor is an N-type metal oxide semiconductor field effect transistor.

9. The AC/DC voltage converter as defined in claim 5, wherein said power transistor, said metal oxide semiconductor field effect transistor and said junction field effect transistor are integrated in a chip.
